(19) United States
(12) Patent Application Publication
(10) Pub. No.: US 2004/0043513 A1
(43) Pub. Date: Mar. 4, 2004

(54) Method of transferring processed body and processing system for processed body

(76) Inventors: Shigeru Ishizawa, Nirasaki-Shi Yamanashi-Ken (JP); Kiyohito Iijima, Nirasaki-Shi Yamanashi-Ken (JP)

Correspondence Address: SMITH, GAMBRELL & RUSSELL, LLP, 1850 M STREET, N.W., SUITE 800, WASHINGTON, DC, 20036, US

(21) Appl. No.: 10/415,993

(22) PCT Filed: Nov. 7, 2001
(86) PCT No.: PCT/JP01/09749

(30) Foreign Application Priority Data
Nov. 7, 2000 (JP) 2000-339682

(51) Int. Cl. H01L 21/00

(52) U.S. Cl. 438/1

(57) ABSTRACT

There is provided a transfer method for transferring a processing object, which is miniaturized to have a small occupying area and which has a transfer mechanism capable of carrying out a teaching operation in a short time. In a processing system for processing a processing object, which comprises a positioning system 32 for positioning a processing object W, processing devices 12A and 12B for carrying out a predetermined processing to the processing object, and a transfer mechanism having upper and lower transfer arms 70 and 72 which are arranged in upper and lower stages and which are capable of being separately controlled to transfer the processing object to the processing device, only the upper transfer arm 70 is used when an unprocessed object positioned by the positioning system is transferred to the processing device, and only the lower transfer arm 72 is used when a processed object in the processing device is transferred.

### BACKGROUND OF THE INVENTION

1. Technical Field

The present invention relates generally to a transfer method and processing system for a processing object, such as a semiconductor wafer, to which a predetermined processing is carried out.

2. Background Art

In a typical system for producing a semiconductor device, various processing devices are combined, and a transfer mechanism is provided for automatically delivering a wafer between these processing devices and between the processing devices and a cassette which houses therein a large number of semiconductor wafers. This transfer mechanism has a transfer arm portion which is capable of bending and stretching, swiveling and vertically moving. The transfer mechanism is designed to horizontally move the transfer arm portion to a transfer position to transfer the wafers to a predetermined position.

In this case, it is not only required to prevent the transfer arm from interfering or colliding with another member while the transfer arm portion is operated, but it is also required to appropriately hold a wafer, which is located at a certain place, to transfer the wafer to a target position to accurately deliver the wafer to an appropriate place within a dislocation quantity of, e.g. ±0.1 mm. Therefore, a so-called teaching operation is carried out for causing a control part, such as a computer, which controls the operation of the transfer arm portion, to store an important position, such as a place to which a wafer is transferred on a transfer path of the transfer arm portion. The teaching method of this type is disclosed in, e.g. Japanese Patent Laid-Open Nos. 7-193112, 9-252039 and 2000-127069.

Recently, a transfer mechanism having two transfer arm portions is often used so as to be capable of holding a plurality of, e.g. two, semiconductor wafers, at a time in order to enhance the efficiency of transfer of semiconductor wafers. The transfer mechanism of this type has two transfer arm portions which are capable of, e.g. bending and stretching and extending on the same horizontal plane in the opposite directions and swiveling and so forth. When a semiconductor wafer is transferred, the transfer mechanism is designed to cause a transfer arm portion, which is nearer to the wafer to be transferred, to hold and transfer the wafer, to shorten the time required to transfer the wafer, to improve throughput.

By the way, in the above described transfer mechanism, there are some cases where the whole transfer mechanism rotates while both of the transfer arm portions horizontally hold the wafer, respectively. Therefore, there is a problem in that the whole system for housing therein the whole transfer mechanism is very large in order to ensure a space required to carry out rotation and so forth. In particular, since a wafer which will be the main-current wafer in future has a diameter of 300 mm, it is required to provide a space having a diameter of about 1 m in order to rotate the transfer mechanism while the wafers are arranged on the same horizontal plane, so that it is not possible to avoid the enlargement of the size of the system.

Moreover, as described above, since the transferred position of the wafer must be accurately positioned when the wafer is transferred into a processing device, the transferred position must be taught to both transfer arms with a very high accuracy when a so-called teaching for teaching the transferred position to both transfer arm portions is carried out, so that there is a problem in that it is a lot of time to carry out the teaching.

### DISCLOSURE OF THE INVENTION

The present invention has been made in order to effectively solve the above described problems. It is an object of the present invention to a method for transferring a processing object, which is miniaturized to have a small occupying area and which can carry out a teaching operation in a short time, and a system for processing a processing object, the system having a transfer mechanism.

According to a first aspect of the present invention, there is provided a method for transferring a processing object in a processing system for processing the processing object, the processing system comprising a positioning system for positioning the processing object, a processing device for carrying out a predetermined processing to the processing object, and a transfer mechanism having upper and lower transfer arms which are arranged in upper and lower stages and which are capable of being separately controlled to transfer the processing object to the processing device, wherein only the upper transfer arm is used when an unprocessed object positioned by the positioning system is transferred to the processing device, and only the lower transfer arm is used when a processed object in the processing device is transferred.

According to the present invention, only the upper transfer arm is used when the object positioned by the positioning system is transferred to the processing device, and only the lower transfer arm is used when the processed object in the processing device is transferred, so that it is possible to prevent particles, which are produced from the processed object held by the lower transfer arm, from adhering to the unprocessed object held by the upper transfer arm.

According to a second aspect of the present invention, there is provided a method for transferring a processing object in a processing system for processing the processing object, the processing system comprising a positioning system for positioning the processing object, a processing device for carrying out a predetermined processing to the processing object, and a transfer mechanism having upper and lower transfer arms which are arranged in upper and lower stages and which are capable of being separately controlled to transfer the processing object to the processing device, the method comprising the steps of: transferring an unprocessed object, which is positioned by the positioning system, to the processing device by means of the upper transfer arm of the transfer mechanism; and receiving a processed object, which is processed by the processing device, by means of the lower transfer arm, and delivering the unprocessed object, which is positioned to be held by the upper transfer arm, to the processing device.

According to the present invention, it is possible to transfer the object to the processing device without allowing particles, which are produced from the processed object, to adhere to the object positioned by the positioning system, and it is possible to effectively and smoothly receive the processed object from the processing device and deliver the positioned and unprocessed object to the processing device.

In the first and second aspects of the present invention, the method may comprise a step of previously holding an unprocessed object, which is not positioned, by the lower transfer arm when a positioned object, which is mounted on the positioning system, is replaced with the unprocessed object to be transferred, and transferring the unprocessed object, which is held by the lower transfer arm, to the positioning system after the positioned object is received by the upper transfer arm.

If the lower and upper transfer arms are thus used, it is possible to transfer the unprocessed object, which is not positioned, to the positioning system, and it is possible to receive the positioned object by the upper transfer arm to transfer the object to the processing device, so that it is possible to smoothly position the unprocessed object, which is not positioned, in the positioning system.

In the first and second aspects of the present invention, the transfer precision of the upper transfer arm may be more accurately adjusted than the transfer precision of the lower transfer arm when a predetermined motion of the transfer mechanism is taught.

Thus, the position precision may be low when the teaching operation for the lower transfer arm is carried out if the position is accurately adjusted when the teaching operation for the upper transfer arm is carried out, so that it is possible to rapidly and simply carry out the teaching operation.

According to a third aspect of the present invention, there is provided a method for transferring a processing object in a processing system for processing the processing object, the processing system comprising a processing device for carrying out a predetermined processing to the processing object, and a transfer mechanism having upper and lower transfer arms which are arranged in upper and lower stages and which are capable of being separately controlled to transfer the processing object to the processing device, wherein only the lower transfer arm is used when a processed object is received from the processing device, and only the upper transfer arm is used when an unprocessed object is delivered to the processing device.

According to the present invention, in the processing system regardless of the presence of a positioning system, only the upper transfer arm is used when the unprocessed object is transferred to the processing device, and only the lower transfer arm is used when the processed object in the processing device is transferred, so that it is possible to prevent particles, which are produced from the processed object held by the lower transfer arm, from adhering to the unprocessed object held by the upper transfer arm.

According to a fourth aspect of the present invention, there is provided a method for transferring a processing object in a processing system for processing the processing object, the processing system comprising a processing device for carrying out a predetermined processing to the processing object, and a transfer mechanism having upper and lower transfer arms which are arranged in upper and lower stages and which are capable of being separately controlled to transfer the processing object to the processing device, wherein only the lower transfer arm is used when a processed object is received from the processing device, and only the upper transfer arm is used when an unprocessed object is delivered to the processing device.

According to the present invention, the transfer arms of the transfer mechanism are arranged in the upper and lower two stages, so that the transfer mechanism itself can be miniaturized to greatly decrease the space occupied by the transfer mechanism. In addition, only the upper transfer arm is used when the object positioned by the positioning system is transferred to the processing device, and only the lower transfer arm is used when the processed object in the processing device is transferred, so that it is possible to prevent particles, which are produced from the processed object held by the lower transfer arm, from adhering to the unprocessed object held by the upper transfer arm.

The transfer precision of the upper transfer arm may be more accurately adjusted than the transfer precision of the lower transfer arm.

Thus, the position precision may be low when the teaching operation for the lower transfer arm is carried out if the position is accurately adjusted when the teaching operation for the upper transfer arm is carried out, so that it is possible to rapidly and simply carry out the teaching operation.

According to a fifth aspect of the present invention, there is provided a processing system comprising: a processing device for carrying out a predetermined processing to the processing object; and a transfer mechanism for transferring the processing object to the processing device, the transfer mechanism including: upper and lower transfer arms which are arranged in upper and lower stages and which are capable of being separately controlled to transfer the processing object, and a control part for causing only the lower transfer arm to be used when a processed object in the processing device is received, and for causing only the upper transfer arm to be used when an unprocessed object is delivered to the processing device.

According to the present invention, in the processing system regardless of the presence of a positioning system, the transfer arms of the transfer mechanism are arranged in the upper and lower two stages, so that the transfer mechanism itself can be miniaturized to greatly decrease the space occupied by the whole mechanism. In addition, only the upper transfer arm is used when the unprocessed object is transferred to the processing device, and only the lower transfer arm is used when the processed object in the processing device is transferred, so that it is possible to prevent particles, which are produced from the processed object held by the lower transfer arm, from adhering to the unprocessed object held by the upper transfer arm.

### BRIEF DESCRIPTION OF THE DRAWINGS

FIG. 1 is a schematic diagram showing a processing system for processing a processing object according to the present invention;

FIG. 2 is a side view showing a positioning system;

FIG. 3 is a plan view showing a state that a transferring object is mounted on a positioning system;

FIG. 4 is a perspective view showing a transfer mechanism;

FIG. 5 is a flow chart showing a method for transferring a wafer which is a processing object when an actual process is carried out; and

FIG. 6 is a schematic diagram showing another example of a processing system for processing a processing object according to the present invention.

### BEST MODE FOR CARRYING OUT THE INVENTION

Referring to the accompanying drawings, a preferred embodiment of a system for processing a processing object and a method for transferring a processing object according to the present invention will be described below in detail.

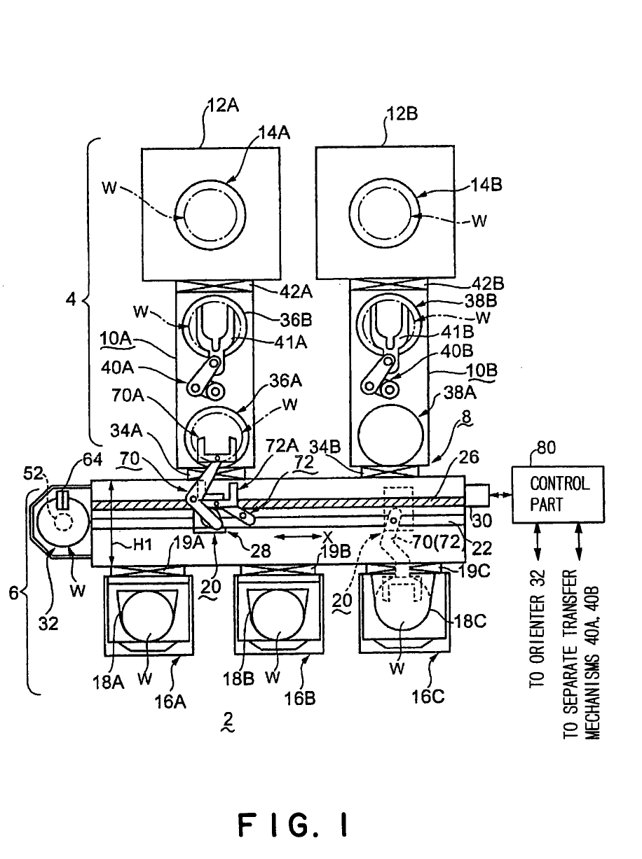

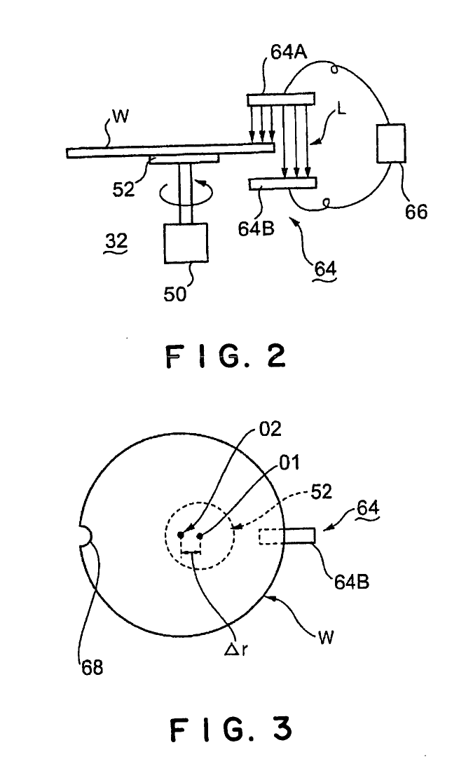

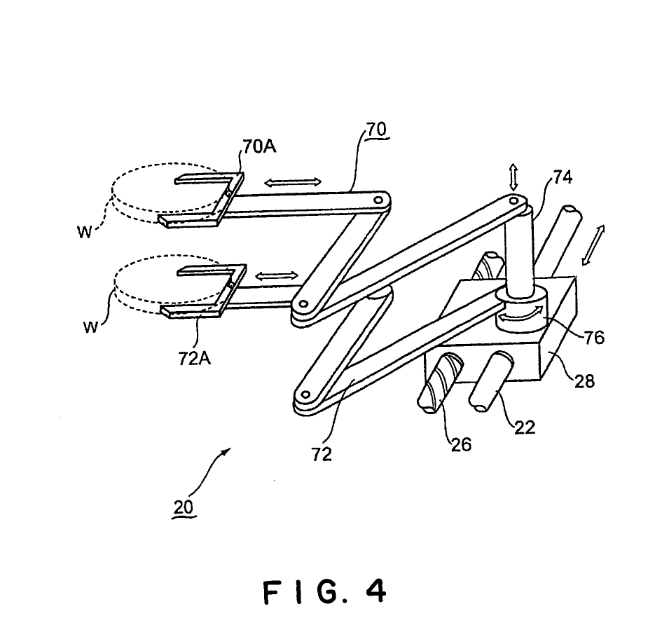

FIG. 1 is a schematic diagram showing a processing system for processing a processing object according to the present invention, FIG. 2 is a side view showing a positioning system, FIG. 3 is a plan view showing a state that a transferring object is mounted on a positioning system, and FIG. 4 is a perspective view showing a transfer mechanism. A case where a semiconductor wafer is used as a processing object will be described below.

First, referring to FIG. 1, a processing system for processing a processing object will be described. This processing system 2 generally comprises a processing unit 4 for carrying out various processes, such as deposition and etching, to a semiconductor wafer W serving as a processing object, and a transfer unit 6 for carrying the wafer W in and out of the processing unit 4. The transfer unit 6 has a common transfer chamber 8 shared when the wafer W is transferred.

The processing unit 4 has one or a plurality of, e.g. two, processing devices 12A and 12B in the shown embodiment, and load-lock chambers 10A and 10B which are communicated with the respective processing devices and which can be evacuated. The processing unit 4 is designed to carry out the same kind of processes or different kinds of processes to the wafer W in the respective processing devices 12A and 12B. In the processing devices 12A and 12B, supporting tables 14A and 14B for supporting thereon the wafer W are provided, respectively.

On the other hand, the common transfer chamber 8 of the transfer unit 6 comprise a laterally enlarged box in which an inert gas, such as N₂ gas, and clean air circulate. On one side of the laterally enlarged box, one or a plurality of, e.g. three, cassette tables 16A, 16B and 16C for supporting thereon three cassette vessels are provided in the shown embodiment. On each of the cassette tables, the cassette vessels 18A through 18C can be mounted one by one. Each of the cassette vessels 18A through 18C can house therein, e.g. twenty five wafers W at the maximum, in multistage at regular intervals, and is filled with, e.g. N₂ gas, to be closed. The wafer can be carried in and out of the common transfer chamber 8 via gate valves 19A through 19C.

In the common transfer chamber 8, there is provided a transfer mechanism 20 which transfers the wafer W in longitudinal directions and which is a feature of the present invention. The transfer mechanism 20 is slidably supported on a guide rail 22 which extends in longitudinal directions in the central portion of the common transfer chamber 8. The guide rail 22 is provided with a moving mechanism, e.g. a ball screw 26. This ball screw 26 engages a screw hole (not shown) of a base 28 of the transfer mechanism 20. Therefore, if a drive motor 30 having the ball screw 26 at its end is rotated, the transfer mechanism 20 moves in X direction along the guide rail 22. Furthermore, a linear motor serving as a moving mechanism may be used for moving the base 28 on the guide rail 20.

The other end of the common transfer chamber 8 is provided with an orienter 32 serving as a positioning system for positioning the wafer. In the middle of the common transfer chamber 8 in longitudinal directions, the two load-lock chambers 10A and 10B capable of being evaluated for connecting the two processing devices 12A and 12B are provided via gate valves 34A and 34B, respectively. In each of the load-lock chambers 10A and 10B, there are provided a pair of buffer supporting tables 36A, 36B and 38A, 38B for temporarily supporting the wafer W to allow the wafer W to stand by. It is assumed that the buffer supporting tables 36A and 38A on the side of the common transfer chamber 8 are first buffer supporting tables, and the buffer supporting tables 36B and 38B on the opposite side are second buffer supporting tables. Between the buffer supporting tables 36A and 36B and between the buffer supporting tables 38A and 38B, there are provided separate transfer mechanisms 40A and 40B, each of which comprises an articulated arm capable of bending and stretching, swiveling and vertically moving. The tip ends of the separate transfer mechanisms 40A and 40B are provided with forks 41A and 41B at their tips for delivering the wafer W between the first and second buffer supporting tables 36A, 36B and 38A, 38B. The other ends of the load-lock chambers 10A and 10B are connected to the processing devices 12A and 12B via gate valves 42A and 42B capable of being open and closed, respectively. Furthermore, the wafer is carried in and out of the processing devices 12A and 12B by means of the separate transfer mechanisms 40A and 40B which are provided so as to correspond thereto, respectively.

Also as shown in FIGS. 2 and 3, the orienter 32 has a reference table 52 which is rotated by a drive motor 50. The orienter 32 is designed to rotate while the wafer W is supported on the reference table 52. On the outer periphery of the reference table 52, an optical sensor 64 for detecting the peripheral portion of the wafer W is provided. The optical sensor 64 comprises a linear light emitting element 64A having a predetermined length arranged so as to extend in radial directions, and a light receiving element 64B arranged so as to correspond thereto via the peripheral portion of the wafer. The optical sensor 64 is designed to cause the end portion of the wafer to be irradiated with curtain-like laser light L to detect the variation therein. A detection operating part 66 can recognize an eccentric quantity and eccentric direction of the wafer W, and the rotational position, i.e. orientation, of a cut-out mark, e.g. a notch 68, formed in the wafer W.

In FIG. 3, O1 denotes the center (rotation center) of the reference table 52, and O2 denotes the center of the wafer W. Therefore, the eccentric quantity is Ar. Furthermore, the cut-out mark is the notch 68 in the case of a 300 mm wafer, and is a notch or orientation flat in the case of 8 inch or 6 inch wafer.

Also as shown in FIG. 4, the transfer mechanism 20 has two articulated transfer arms 70 and 72 which are arranged in upper and lower two stages. The tip ends of the transfer arms 70 and 72 are provided with two-way forks 70A and 72A, respectively. The forks 70A and 72A are designed to directly hold the wafer W, respectively. Therefore, each of the transfer arms 70 and 72 is designed to bend and stretch in R directions which are radial directions from its center. The bending and stretching motions of the transfer arms 70 and 72 are capable of being separately controlled.

The rotation shafts 74 and 76 of the transfer arms 70 and 72 are coaxially and rotatably connected to the base 28, respectively, so as to be capable of integrally rotating in θ directions which are swivel directions with respect to, e.g. the base 28. Moreover, the rotation shafts 74 and 76 are also capable of, e.g. integrally moving in vertical directions, i.e. Z directions, about the base 28. Therefore, all of position coordinates are expressed as coordinates of X, Z, R and θ. Of course, the coordinates of the respective shafts can recognize a displacement quantity from a preset reference point by, e.g. an encoder.

The transfer mechanism 20 should not be limited to the structure shown in FIG. 4 if it can be provided with the transfer arms 70 and 72 in upper and lower two stages. Referring to FIG. 1 again, in order to control the operation of the whole processing system including the positioning operations of the transfer mechanism 20 and transfer mechanisms 40A and 40B, a control part 80 comprising, e.g. a microcomputer, is provided. The control part 80 stores therein position coordinates and so forth which are required during a positioning teaching operation which will be described later.

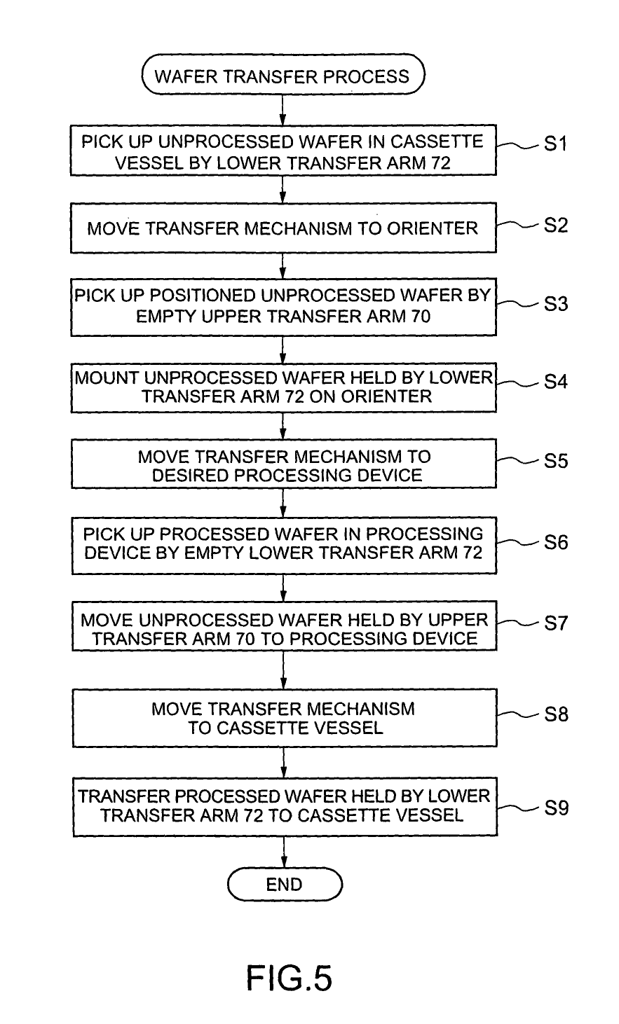

Also referring to FIG. 5, a transferring method according to the present invention carried out by the above described processing system 2 will be described below.

FIG. 5 is a flow chart showing a method for transferring a wafer W when an actual process is carried out.

First, before a semiconductor wafer W is actually processed, a teaching operation is carried out so that the transfer mechanism 20 can accurately transfer the wafer W to a correct position when the transfer mechanism 20 transfer the wafer W. In this case, according to the present invention, when the wafer W positioned by the orienter 32 is transferred to the load-lock chamber 10A or 10B, the upper-stage transfer arm 70 of the two transfer arms 70 and 72 is always used in order to prevent particles from adhering thereto, so that a teaching operation for accurately positioning only the upper-stage transfer arm 70 is previously carried out. As is well known, this teaching operation is carried out by accurately and manually arranging, e.g. the wafer W, on the fork 70A of the transfer arm 70 at an appropriate position, accurately and manually arranging the transfer arm 70 on the first buffer supporting table 36A of the load-lock chamber 10A at an appropriate position, and causing the control part 80 to describe coordinates at this time. In fact, such an operation is repeated a plurality of times to take mean coordinates. Such a teaching operation with a high positional precision is also carried out with respect to the first buffer supporting table 38A of the other load-lock chamber 10B.

According to the present invention, such a teaching operation with a high positional precision may be carried out with respect to only the upper-stage transfer arm 70 without being carried out with respect to the lower-stage transfer arm 72 which does not transfer the wafer from the orienter 32, and a teaching operation with a low positional precision may be simply carried out with respect to the lower-stage transfer arm 72 to such an extent that the wafer does not interfere with other members.

An actual transfer method, which is carried out when a semiconductor wafer is processed, will be described below.

It is assumed that the transferred semiconductor wafer has been positioned by the orienter 32 and also has been processed in the processing device.

First, an unprocessed semiconductor wafer W is picked up from a cassette vessel on one of the three cassette tables, e.g. the cassette vessel 18C on the cassette table 16C, and held by the fork 72A by driving the lower-stage transfer arm 72 of the transfer mechanism 20 (S1), and the wafer W is transferred to the orienter 32 by moving the transfer mechanism 20 in X direction (S2).

Then, the unprocessed semiconductor wafer W on the rotating table 52, which has been transferred and positioned by the orienter 32, is picked up and held by the fork 70A by driving the upper-stage empty transfer arm 70, the transfer precision of which has been accurately adjusted (S3). Thus, the rotating table 62 is emptied.

Then, the unprocessed wafer held by the fork 72A of the transfer arm 72 is mounted on the empty rotating table 52 (S4). Furthermore, this wafer is positioned before the next unprocessed wafer is transferred.

Then, the unprocessed wafer held by the upper-stage transfer arm 70 as described above is moved to a desired processing device of the two processing devices 12A and 12B, e.g. the load-lock chamber 10A of the processing device 12A, by moving the transfer mechanism 20 in X direction (S5)

The processed wafer, which was transferred and to which predetermined processes, e.g. deposition and etching, were carried out in the processing device 12A, has been transferred to the first buffer supporting table 36A in the load-lock chamber 10A to stand by. At this time, if the gate valve 34A is open, the pressure-regulated load-lock chamber 10A is communicated with the common transfer chamber 8. Then, first, the lower-stage empty transfer arm 72 is driven to pick up and hold the processed wafer W, which stands by on the first buffer supporting table 36A, by the fork 72A (S6). Thus, since the first buffer supporting table 36A is emptied, the upper-stage transfer arm 70 is driven to transfer the unprocessed wafer W, which is held by the fork 70A, to the first buffer supporting table 36A (S7).

Thus, when the unprocessed wafer is replaced with the processed wafer, the transfer mechanism 20 simultaneously hold the unprocessed and processed wafers. However, since the unprocessed wafer is held by the upper-stage transfer arm 70 and the processed wafer is held by the lower-stage transfer arm 72 as described above, the processed wafer is positioned below the unprocessed wafer. Therefore, even if an undesired film produced during deposition is peeled off from the processed wafer or shavings produced during etching are peeled off to drop particles, it is possible to prevent the particles from adhering to the unprocessed wafer.

After the unprocessed wafer is thus held by the lower-stage transfer arm 72, the transfer mechanism 20 is moved in X direction to a predetermined cassette vessel, e.g. 18C (S8). Then, the processed wafer W held by the lower-stage transfer arm 72 is transferred to a predetermined position in the cassette vessel 18A (S9). Furthermore, before this, the gate valve 34A is closed in the load-lock chamber 10A, and the unprocessed wafer on the first buffer supporting table 36A is transferred to the supporting table 14A in the processing device 12A by means of the separate transfer mechanism 40A. Then, a predetermined processing is carried out therein.

Since the upper-stage transfer arm 70 is thus always used when the unprocessed wafer W is transferred from the orienter 32 to the load-lock chamber 10A or 10B of one processing device 12A or 12B, the unprocessed wafer is always positioned above the processed wafer even if the processed wafer crosses the unprocessed wafer at vertical positions when the unprocessed wafer is replaced with the processed wafer. Therefore, it is possible to prevent particles from adhering to the unprocessed wafer.

Since the upper-stage transfer arm 70 is always used when the positioned wafer is transferred from the orienter 32, the teaching operation with a high transfer precision is carried out with respect to only the upper-stage transfer arm 70 and is not required to be carried out with respect to the lower-stage transfer arm 72, so that the teaching operation can be rapidly and simply carried out.

Since the two transfer arms 70 and 72 are arranged in the upper and lower two stages so as to overlap in vertical directions, the plane size thereof can be greatly decreased unlike conventional systems wherein two transfer arms are arranged on the same horizontal plane. In fact, in conventional systems, the width H1 of the common transfer chamber 8 in FIG. 1 must be about 100 cm in the case of a wafer having a size of 300 mm. However, in the processing system according to the present invention, the width H1 is only about 40 to 50 cm, so that the width H1 can be greatly decreased.

In this preferred embodiment, as shown by S1 in FIG. 5, the lower-stage transfer arm 72 is used when the unprocessed wafer in the cassette vessel is picked up. However, when the orienter 32 is empty, any one of the transfer arms in the upper and lower stages may be used.

While the processing devices 12A and 12B having both of the load-lock chambers 10A and 10B has been described as an example since the vacuum processing has been carried out therein, it is not always required to provide the load-lock chambers in accordance with the form of a processing, e.g., in the case of a processing device for carrying out oxidation and diffusion at ordinary pressure.

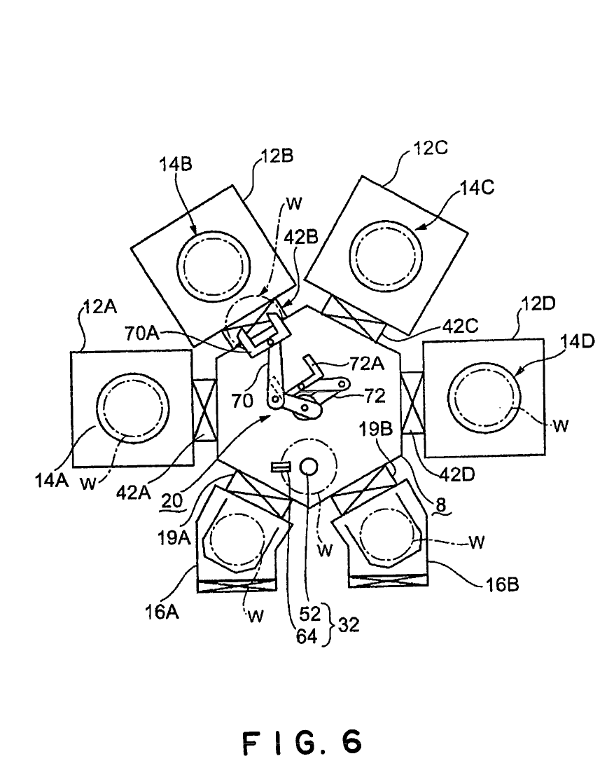

While the processing system wherein the load-lock chambers 10A and 10B are connected to the elongated box-shaped common transfer chamber 8 via the processing devices 12A and 12B and wherein the transfer mechanism 20 is slidably provided in the common transfer 8, has been described as an example, the present invention should not be limited thereto. For example, as shown in FIG. 6, the present invention can be applied to a so-called cluster tool type processing system wherein the same transfer mechanism 20 (without no slide in X directions) as that shown in FIG. 1 is provided at the center in a polygonal, e.g., hexagonal, common transfer chamber 8, and, e.g. four processing devices 12A through 12D and two cassette chambers 16A and 16B are provided around the transfer mechanism 20.

In this case, an orienter 32 comprising a reference table 52 and an optical sensor 64 is provided in a part of the hexagonal common transfer chamber 8. In the same manner as that described above, the upper-stage transfer arm 70 of the transfer mechanism 20 is used when the semiconductor wafer W positioned by the orienter 32 is transferred to the respective processing devices 12A through 12D. Also in this case, the same advantageous effects as those described above can be obtained.

Thus, the present invention can be applied to all of processing systems including the orienter 32. Therefore, of course, the present invention can be applied to a so-called cluster tool type processing system wherein a plurality of processing devices and an orienter are connected to the respective sides of a polygonal, e.g. rectangular or hexagonal, common transfer chamber, or a processing device wherein an orienter is included in the above described common transfer chamber.

While the semiconductor wafer W has been described as an example of a processing object, the present invention should not be limited thereto, but the present invention maybe applied to glass substrates and LCD substrates.

As described above, according to the present invention, since the transfer arms of the transfer mechanism are provided in upper and lower two stages, the transfer mechanism itself can be miniaturized to greatly decrease the space occupied by the whole system. In addition, since the lower-stage transfer arm is used when the processed object is held to be transferred, it is possible to prevent particles from adhering to the unprocessed object even if the unprocessed object is simultaneously held by, e.g. the upper-stage transfer arm.

In addition, the teaching operation can be rapidly and simply carried out since the positional precision is low when the teaching operation may be carried out with respect to the lower-stage transfer arm if the position adjustment is accurately carried out when the teaching operation is carried out with respect to the upper-stage transfer arm.

What is claimed is:

1. A method for transferring a processing object in a processing system for processing the processing object, said processing system comprising a positioning system for positioning the processing object, a processing device for carrying out a predetermined processing to the processing object, and a transfer mechanism having upper and lower transfer arms which are arranged in upper and lower stages and which are capable of being separately controlled to transfer the processing object to the processing device,
wherein only said upper transfer arm is used when an unprocessed object positioned by said positioning system is transferred to said processing device, and only said lower transfer arm is used when a processed object in said processing device is transferred.

2. A method for transferring a processing object in a processing system for processing the processing object, said processing system comprising a positioning system for positioning the processing object, a processing device for carrying out a predetermined processing to the processing object, and a transfer mechanism having upper and lower transfer arms which are arranged in upper and lower stages and which are capable of being separately controlled to transfer the processing object to the processing device, said method comprising the steps of:
transferring an unprocessed object, which is positioned by said positioning system, to said processing device by means of said upper transfer arm of said transfer mechanism; and
receiving a processed object, which is processed by said processing device, by means of said lower transfer arm, and delivering said unprocessed object, which is positioned to be held by said upper transfer arm, to said processing device.

3. A method for transferring a processing object as set forth in claim 1 or 2, which further comprises a step of previously holding an unprocessed object, which is not positioned, by said lower transfer arm when a positioned object, which is mounted on said positioning system, is replaced with said unprocessed object to be transferred, and transferring said unprocessed object, which is held by said lower transfer arm, to said positioning system after said positioned object is received by said upper transfer arm.

4. A method for transferring a processing object as set forth in claim 1 or 2, wherein a transfer precision of said upper transfer arm is more accurately adjusted than a transfer precision of said lower transfer arm when a predetermined motion of said transfer mechanism is taught.

5. A method for transferring a processing object in a processing system for processing the processing object, said processing system comprising a processing device for carrying out a predetermined processing to the processing object, and a transfer mechanism having upper and lower transfer arms which are arranged in upper and lower stages and which are capable of being separately controlled to transfer the processing object to the processing device,
wherein only said lower transfer arm is used when a processed object is received from said processing device, and only said upper transfer arm is used when an unprocessed object is delivered to said processing device.

6. A processing system comprising:
a positioning system for positioning a processing object;
a processing device for carrying out a predetermined processing to the processing object; and
a transfer mechanism for transferring the processing object to the processing device, said transfer mechanism including:
upper and lower transfer arms which are arranged in upper and lower stages and which are capable of being separately controlled to transfer the processing object, and
a control part for causing only said upper transfer arm to be used when an unprocessed object positioned by said positioning system is transferred to said processing device, and for causing only said lower transfer arm to be used when a processed object in said processing device is transferred.

7. A processing system as set forth in claim 6, wherein a transfer precision of said upper transfer arm is more accurately adjusted than a transfer precision of said lower transfer arm.

8. A processing system comprising:
a processing device for carrying out a predetermined processing to the processing object; and
a transfer mechanism for transferring the processing object to the processing device, said transfer mechanism including:
upper and lower transfer arms which are arranged in upper and lower stages and which are capable of being separately controlled to transfer the processing object, and
a control part for causing only said lower transfer arm to be used when a processed object in said processing device is received, and for causing only said upper transfer arm to be used when an unprocessed object is delivered to said processing device.
